(19) United States
(12) Patent Application Publication
(10) Pub. No.: US 2026/0099649 A1
(43) Pub. Date: Apr. 9, 2026

(54) HYDROGEN FUELING TEST METHOD AND SYSTEM USING ON-SITE DATA ON VEHICLE SIDE AND FUELING STATION SIDE

(71) Applicants: HYUNDAI MOTOR COMPANY, Seoul (KR); KIA CORPORATION, Seoul (KR); INDUSTRIAL ACADEMIC COOPERATION FOUNDATION OF HOSEO UNIVERSITY, Asan-Si, Chungcheongnam-DO (KR)

(72) Inventors: Cheol Woo Park, Hwaseong-Si, Gyeonggi-Do (KR); Heon Chang Kim, Hwaseong-Si, Gyeonggi-Do (KR); Yong Ho Chung, Asan-Si, Chungcheongnam-Do (KR)

(21) Appl. No.: 19/115,347

(22) PCT Filed: Sep. 26, 2023
(86) PCT No.: PCT/KR2023/014853

§ 371 Date: Mar. 26, 2025

(30) Foreign Application Priority Data
Sep. 26, 2022 (KR) 10-2022-0121479
Sep. 26, 2022 (KR) 10-2022-0121480

(51) Int. Cl. G06F 30/27; F17C 13/02

(52) U.S. Cl. CPC G06F 30/27; F17C 13/02; F17C 2221/012

(57) ABSTRACT

A method according to an embodiment of the present disclosure comprises the steps of: transmitting, to a hydrogen fueled mobility, hydrogen fueling control-related information affecting the state of hydrogen in a mobility tank of the hydrogen fueled mobility; acquiring, as a feedback to the hydrogen fueling control-related information, on-site data on a change in the state of hydrogen in the mobility tank; and on the basis of the on-site data on a change in the state of hydrogen in the mobility tank, corresponding to the hydrogen fueling control-related information, updating a model for a hydrogen fueling process for the hydrogen fueled mobility, corresponding to the hydrogen fueling control-related information.

### TECHNICAL FIELD

The present disclosure relates to a control technology for hydrogen fueling/supply for a hydrogen fueled mobility and, more particularly, to a hydrogen fueling process enhancing an efficiency of the hydrogen fueling/supply and improving a speed and a real-time operability of the hydrogen fueling/supply, and a test platform for the process.

### BACKGROUND ART

The description in this section merely provides background information of embodiments of the present disclosure and is not intended to specify prior arts of the present disclosure.

A hydrogen fueled mobility, a hydrogen electric vehicle, or a fuel cell electric vehicle (FCEV) refers to a vehicle driven by electrical energy generated by a reaction of high-pressure hydrogen stored in the vehicle and oxygen in the air and producing little pollution.

The hydrogen fueled mobility is a concept including not only the hydrogen electric vehicle and the fuel cell electric vehicle employing a fuel cell system utilizing the hydrogen as an energy source but also another kind of mobilities employing an internal combustion engine (ICE) to generate power and being driven by the power generated by the ICE using the hydrogen as fuel.

As is known in the art, the hydrogen electric vehicle not only exhausts pure water (H2O) vapor in the course of generating the electricity but also removes ultrafine dusts in the air while being driven, and thus are attracting attention as a future eco-friendly mobility. Since the fuel, i.e. hydrogen, is abundant on earth and the energy production process is eco-friendly, the hydrogen electric vehicle is spotlighted as a technology with the potential to be utilized across industries.

The hydrogen electric vehicle produces electrical energy by supplying the high-pressure hydrogen stored safely in a hydrogen fuel storage tank and the oxygen introduced through an air supply system to a fuel cell stack and causing an electrochemical reaction between the hydrogen and the oxygen to occur. The electrical energy produced in the fuel cell stack is converted into kinetic energy through a motor to drive the hydrogen electric vehicle, and an operating hydrogen electric vehicle discharges only the pure water vapor through an exhaust port.

The fuel cell system provides power to the vehicle similarly to an engine in an internal combustion engine vehicle. A fuel cell, which is also referred to as a “tertiary battery,” is a unit generating the electrical energy needed to drive the hydrogen electric vehicle. The fuel cell converts the chemical energy into the electrical energy through electrochemical reactions between the hydrogen and the oxygen. The electrical energy produced by the reactions originates from pure chemical reactions and does not produce any exhaust gases such as carbon dioxide unlike fossil fuels. Fuel cells are often categorized by the type of the fuel or an electrolyte. Leading fuel cell technologies may include a proton exchange membrane fuel cell (PEMFC), a solid oxide fuel cell (SOFC), and a molten carbonate fuel cell (MCFC). The components producing the electrical power using the fuel cells in the hydrogen electric vehicle includes the fuel cell stack, a hydrogen supply system, and an air supply system, and a thermal management system.

An efficient generation of the electrical energy in the fuel cell stack requires an assistance of the operation mechanism. Among several apparatuses in the operation mechanism, the hydrogen supply system plays a role of changing a pressure condition of the hydrogen safely stored in the hydrogen fuel storage tank from a high pressure to a low pressure and transfer to the fuel cell stack. In addition, the hydrogen supply system may increase a hydrogen supply efficiency by recirculating through a recirculation line.

A thermal management system may release heat generated while the fuel cell stack undergoes an electrochemical reaction to the outside and circulate cooling water to maintain a temperature of the fuel cell stack within a certain range. Thermal management system may affect the output and lifespan of the fuel cell stack.

A hydrogen fueled vehicle other than the hydrogen electric vehicle is also a vehicle that uses the hydrogen as the fuel. The hydrogen fueled car is driven by an electric motor which is rotated by heat generated by directly burning the hydrogen in the engine. The method of fueling/supplying the hydrogen for the hydrogen fueled car is not much different from the hydrogen fueling/supply method for the hydrogen electric vehicle.

The control scheme for fueling or supply hydrogen to the hydrogen fueled mobility aims to control the hydrogen fueling/supply such that a temperature (T) and pressure (P) of a compressed hydrogen storage system (CHSS) on the fuel cell side are maintained below a certain temperature limit and a pressure limit to ensure the safety.

The hydrogen fueling/supply process, the control scheme, and the protocol thereof in the conventional hydrogen electric vehicle had been stipulated before wired/wireless communications or computing techniques for the control became mature, and thus do not utilize the state-of-art information and communications technologies (ICT) to their full extent.

Furthermore, a technology is required to test the hydrogen fueling/supply process for the hydrogen fueled mobility and validate the process based on real-time on-site data.

### DISCLOSURE OF INVENTION

### Technical Problem

To solve the above problems, one object of the present disclosure is to enhance an efficiency of a hydrogen fueling/supply process and improve a speed and a real-time operability of the hydrogen fueling/supply process while safely fueling/supplying hydrogen fuel.

Another object of the present disclosure is to provide a test method and a test platform enabling a precisely modeling of the hydrogen fueling/supply process based on real-time on-site dynamic data.

Another object of the present disclosure is to provide a test method and a test platform enabling to provide a model capable of precisely controlling the hydrogen fueling/supply process by taking into account a difference between a result of modeling and simulation by a theoretical model and the real-time on-site data or both the result of the modeling and simulation and the real-time on-site data or precisely controlling the hydrogen fueling/supply process by taking into account both the result of the modeling and simulation and the real-time on-site data.

### Technical Solution

According to an aspect of the present disclosure to achieve the above objects, a hydrogen fueling test method for a hydrogen fueled mobility, may include: transmitting hydrogen fueling control related information affecting a state of hydrogen in a mobility tank of the hydrogen fueled mobility to the hydrogen fueled mobility; obtaining on-site data for a change in the state of the hydrogen in the mobility tank as a feedback corresponding to the hydrogen fueling control related information; and updating a model for a hydrogen fueling process for the hydrogen fueled mobility corresponding to the hydrogen fueling control related information based on the on-site data for the change in the state of the hydrogen in the mobility tank corresponding to the hydrogen fueling control related information.

The hydrogen fueling test method according to an exemplary embodiment of the present disclosure may further include: obtaining a difference between a simulation result for the change in the state of the hydrogen in the mobility tank corresponding to the hydrogen fueling control related information and the on-site data for the change in the state of the hydrogen in the mobility tank.

While updating the model, the model for the change in the state of the hydrogen in the mobility tank corresponding to the hydrogen fueling control related information may be updated based on the difference between the simulation result and the on-site data.

The hydrogen fueling test method according to an exemplary embodiment of the present disclosure may further include: obtaining the simulation result for the change in the state of the hydrogen in the mobility tank corresponding to the hydrogen fueling control related information by using a thermodynamic model tracking a transient change in one or more of temperature, pressure, or mass flow of the hydrogen in the mobility tank.

The hydrogen fueling test method according to an exemplary embodiment of the present disclosure may further include: obtaining the simulation result for the change in the state of the hydrogen in the mobility tank corresponding to the hydrogen fueling control related information by applying a predicted hydrogen control request for one or more time intervals at least partly including future obtained by a model predictive control (MPC) technique to the model for the hydrogen fueling process.

The model for the hydrogen fueling process corresponding to the hydrogen fueling control related information may be a model trained to predict the change in the state of the hydrogen in the mobility tank based on the hydrogen fueling control related information and the state of the hydrogen in the mobility tank.

In particular, the model for the change in the state of the hydrogen in the mobility tank corresponding to the hydrogen fueling control related information may be a model trained to predict a future change in the state of the hydrogen in the mobility tank based on one or more of the hydrogen fueling control related information, a current state of the hydrogen in the mobility tank, a state of the hydrogen supplied to the mobility from the dispenser, and/or an ambient temperature.

The model for the hydrogen fueling process corresponding to the hydrogen fueling control related information may be a model trained to predict the change in the state of the hydrogen in the mobility tank according to one or more of each target state of the hydrogen in the mobility tank targeted by the hydrogen fueling control related information and/or each hydrogen fueling protocol.

The model may be an artificial neural network model. In such a case, while the model is updated, parameters of the model may be updated by training to predict the change in the state of the hydrogen in the mobility tank based on the hydrogen fueling control related information and the state of the hydrogen in the mobility tank and using the on-site data for the change in the state of the hydrogen in the mobility tank as ground truth data.

The model may be a model trained to predict the change in the state of the hydrogen in the mobility tank using a model prediction control technique.

The hydrogen fueling test method according to an exemplary embodiment of the present disclosure may further include: after updating the model, replacing at least a part of the hydrogen fueled mobility-side with the model to obtain one or more of the simulation data and/or the on-site data for the change in a state of hydrogen supplied to a dispenser from a fueling station correspondingly to a second control request sent between the dispenser supplying hydrogen to the hydrogen fueled mobility and the fueling station supplying hydrogen to the dispenser.

The hydrogen fueling test method according to an exemplary embodiment of the present disclosure may further include: determining, through a communication, whether the hydrogen fueled mobility is capable of actively responding to the hydrogen fueling control related information and controlling the change in the state of the hydrogen in the mobility tank.

The hydrogen fueling control related information may include one or more of information on a hydrogen fueling control request and/or state information according to an execution result of the hydrogen fueling control request. The hydrogen fueling control request may include a control request for a pressure ramp rate (PRR) for fueling hydrogen in the mobility tank.

The change in the state of the hydrogen in the mobility tank may include a change in one or more of a temperature, a pressure, and/or a state of charge (SOC).

The operations of transmitting the hydrogen fueling control related information to the hydrogen fueled mobility and obtaining the on-site data for the change in the state of the hydrogen in the mobility tank may be performed based on (or by executing) an existing fueling protocol.

The hydrogen fueling test method according to an exemplary embodiment of the present disclosure may further include: obtaining a hydrogen fueling control sequence from the model for the hydrogen fueling process; and reinforcing the existing hydrogen fueling protocol based on the hydrogen fueling control sequence obtained from the model for the hydrogen fueling process.

The hydrogen fueling test method according to an exemplary embodiment of the present disclosure may further include: obtaining result data of an execution of the hydrogen fueling control sequence obtained from the model for the hydrogen fueling process.

The existing hydrogen fueling protocol may be partly reinforced by using the hydrogen fueling control sequence based on a comparison between the result data of the execution of the hydrogen fueling control sequence and on-site data obtained by the existing hydrogen fueling protocol.

According to another aspect of the present disclosure, a hydrogen fueling test system for a hydrogen fueled mobility may include: a communication interface configured to transmit hydrogen fueling control related information affecting a state of hydrogen in a mobility tank of a hydrogen fueled mobility to the hydrogen fueled mobility and receive on-site data for a change in the state of the hydrogen in the mobility tank as a feedback corresponding to the hydrogen fueling control related information; and a controller configured to update a model for the change in the state of the hydrogen in the mobility tank corresponding to the hydrogen fueling control related information based on the on-site data for the change in the state of the hydrogen in the mobility tank corresponding to the hydrogen fueling control related information.

The controller may be configured to obtain a difference between a simulation result for the change in the state of the hydrogen in the mobility tank corresponding to the hydrogen fueling control related information and the on-site data for the change in the state of the hydrogen in the mobility tank.

The controller may be configured to update the model for the change in the state of the hydrogen in the mobility tank corresponding to the hydrogen fueling control related information based on the difference between the simulation result and the on-site data.

The controller may be configured to obtain the simulation result for the change in the state of the hydrogen in the mobility tank corresponding to the hydrogen fueling control related information by using a thermodynamic model tracking a transient change one or more of temperature, pressure, and/or mass flow of the hydrogen in the mobility tank.

The controller may be configured to obtain the simulation result for the change in the state of the hydrogen in the mobility tank corresponding to the hydrogen fueling control related information by applying a predicted hydrogen control request for one or more time intervals at least partly including future obtained by a model predictive control (MPC) technique to the model for the hydrogen fueling process.

The model may be an artificial neural network model. The controller may be configured to update parameters of the model by training a function of predicting the change in the state of the hydrogen in the mobility tank based on the hydrogen fueling control related information and the state of the hydrogen in the mobility tank and using the on-site data for the change in the state of the hydrogen in the mobility tank as ground truth data.

The controller may be configured to determine, through the communication interface, whether the hydrogen fueled mobility is capable of actively responding to the hydrogen fueling control related information and controlling the change in the state of the hydrogen in the mobility tank.

The controller may be configured to execute an existing fueling protocol to transmit the hydrogen fueling control related information to the hydrogen fueled mobility through the communication interface and obtain the on-site data for the change in the state of the hydrogen in the mobility tank through the communication interface.

The controller may be configured to obtain a hydrogen fueling control sequence from the model for the hydrogen fueling process. The controller may be configured to reinforce the existing hydrogen fueling protocol based on the hydrogen fueling control sequence obtained from the model for the hydrogen fueling process.

The controller may be configured to obtain result data of an execution of the hydrogen fueling control sequence obtained from the model for the hydrogen fueling process. The controller may be configured to partly reinforce the existing hydrogen fueling protocol by using the hydrogen fueling control sequence based on a comparison between the result data of the execution of the hydrogen fueling control sequence and on-site data obtained by the existing hydrogen fueling protocol.

### Advantageous Effects

An exemplary embodiment of the present disclosure allows to enhance the efficiency of the hydrogen fueling/supply process and improve the speed and the real-time operability of the hydrogen fueling/supply process while safely fueling/supplying the hydrogen fuel.

An exemplary embodiment of the present disclosure allows to implement a test method and a test platform enabling a precisely modeling of the hydrogen fueling/supply process based on real-time on-site dynamic data.

An exemplary embodiment of the present disclosure allows to implement a test method and a test platform enabling to provide a model capable of precisely controlling the hydrogen fueling/supply process by taking into account the difference between the result of modeling and simulation by a theoretical model and the real-time on-site data or both the result of the modeling and simulation and the real-time on-site data or precisely controlling the hydrogen fueling/supply process by taking into account both the result of the modeling and simulation and the real-time on-site data.

An exemplary embodiment of the present disclosure enables to implement a test method for a hydrogen fueling control ensuring the real-time operability based on a model predictive control (MPC).

An exemplary embodiment of the present disclosure enables to implement a test method for the hydrogen fueling control with an enhanced accuracy in a prediction of a hydrogen fueling result based on an artificial neural network (ANN) model.

### DESCRIPTION OF DRAWINGS

FIG. 1 is a conceptual diagram illustrating an example of a hydrogen fueling process for a hydrogen fueled mobility to which an exemplary embodiment of the present disclosure is applied;

FIG. 2 is a conceptual diagram illustrating an example of a state change that occurs in the hydrogen fueling process for the hydrogen fueled mobility to which an exemplary embodiment of the present disclosure is applied;

FIG. 3 is a conceptual diagram illustrating a hydrogen fueling test platform according to an exemplary embodiment of the present disclosure;

FIG. 4 is a detailed block diagram of a dispenser subsystem shown in FIG. 3;

FIG. 5 is a conceptual diagram illustrating the hydrogen fueling test platform according to an exemplary embodiment of the present disclosure;

FIG. 6 is a conceptual diagram illustrating the hydrogen fueling test platform according to another exemplary embodiment of the present disclosure;

FIG. 7 is a flowchart illustrating a hydrogen fueling test method according to an exemplary embodiment of the present disclosure;

FIG. 8 is a flowchart illustrating a process of configuring the test platform from a theoretical concept of the hydrogen fueling process to a formation of the test platform according to an exemplary embodiment of the present disclosure;

FIG. 9 is a conceptual diagram illustrating a configuration for actively and/or passively performing a control of a temperature of a hydrogen tank in the hydrogen fueled mobility during the hydrogen fueling process for the hydrogen fueled mobility according to an exemplary embodiment of the present disclosure;

FIG. 10 is a flowchart illustrating a process of determining a cooling load (CL) based on the configuration of FIG. 9;

FIG. 11 is a conceptual diagram illustrating an example of an artificial neural network for controlling the hydrogen fueling process for the hydrogen fueled mobility according to an exemplary embodiment of the present disclosure;

FIG. 12 is a conceptual diagram illustrating a concept of a model predictive control for controlling the hydrogen fueling process for the hydrogen fueled mobility according to an exemplary embodiment of the present disclosure;

FIG. 13 is a flowchart illustrating a process of training the artificial neural network for the hydrogen fueling control according to an exemplary embodiment of the present disclosure;

FIG. 14 is a conceptual diagram illustrating a part of the process of FIG. 12 in more detail;

FIG. 15 is a conceptual diagram illustrating another part of the process of FIG. 12 in more detail; and

FIG. 16 is a block diagram showing a generalized configuration of a hydrogen fueling control apparatus, a hydrogen fueling control system, a hydrogen fueling test platform, a hydrogen fueling test system, or a computing system capable of performing at least a portion of the processes of FIGS. 1-15; and

FIGS. 17 and 18 are conceptual diagrams illustrating the hydrogen fueling test platform according to other embodiments of the present disclosure.

### BEST MODE

For a clearer understanding of the features and advantages of the present disclosure, exemplary embodiments of the present disclosure will be described in detail with reference to the accompanied drawings. However, it should be understood that the present disclosure is not limited to particular embodiments disclosed herein but includes all modifications, equivalents, and alternatives falling within the spirit and scope of the present disclosure. In the drawings, similar or corresponding components may be designated by the same or similar reference numerals.

The terminologies including ordinals such as “first” and “second” designated for explaining various components in this specification are used to discriminate a component from the other ones but are not intended to be limiting to a specific component. For example, a second component may be referred to as a first component and, similarly, a first component may also be referred to as a second component without departing from the scope of the present disclosure. As used herein, the term “and/or” may include a presence of one or more of the associated listed items and any and all combinations of the listed items.

In the description of exemplary embodiments of the present disclosure, “at least one of A and B” may mean “at least one of A or B” or “at least one of combinations of one or more of A and B”. In addition, in the description of exemplary embodiments of the present disclosure, “one or more of A and B” may mean “one or more of A or B” or “one or more of combinations of one or more of A and B”.

When a component is referred to as being “connected” or “coupled” to another component, the component may be directly connected or coupled logically or physically to the other component or indirectly through an object therebetween. Contrarily, when a component is referred to as being “directly connected” or “directly coupled” to another component, it is to be understood that there is no intervening object between the components. Other words used to describe the relationship between elements should be interpreted in a similar fashion.

The terminologies are used herein for the purpose of describing particular exemplary embodiments only and are not intended to limit the present disclosure. The singular forms include plural referents as well unless the context clearly dictates otherwise. Also, the expressions “comprises,” “includes,” “constructed,” “configured” are used to refer a presence of a combination of stated features, numbers, processing steps, operations, elements, or components, but are not intended to preclude a presence or addition of another feature, number, processing step, operation, element, or component.

Unless defined otherwise, all terms used herein, including technical or scientific terms, have the same meaning as commonly understood by those of ordinary skill in the art to which the present disclosure pertains. Terms such as those defined in a commonly used dictionary should be interpreted as having meanings consistent with their meanings in the context of related literatures and will not be interpreted as having ideal or excessively formal meanings unless explicitly defined in the present application.

Terms used in the present disclosure are defined as follows.

The hydrogen fueled mobilities generally include not only the hydrogen electric vehicles or hydrogen fuel cell electric vehicles (FCEVs) using the fuel cells but also the internal combustion engine (ICE)-based vehicles using the hydrogen as fuel.

The hydrogen fluid fuel may include gaseous hydrogen fuel or liquid hydrogen fuel.

“Compressed Hydrogen Storage System (CHSS)”: An apparatus which is a part of the fuel cell of a vehicle to compress and store the hydrogen.

“Pressure Relief Device (PRD)”: A device disposed in the CHSS and capable of isolating stored hydrogen from the other part of the fueling system and environment and exhausting the hydrogen to the outside.

“Hydrogen fueling process”: A process of supplying the high-pressure hydrogen from a hydrogen fueling station to the fuel cell and to accumulate the hydrogen in the fuel cell.

“Pressure Ramp Rate (PRR)”: An increase rate of a pressure of CHSS and measured in mega-pascals per minute (MPa/min).

“Average Pressure Ramp Rate (APRR)”: An average of the increase rate of the pressure from the beginning to the end of the hydrogen fueling.

“Precooling”: A process of cooling the hydrogen in a hydrogen fueling station before the fueling.

“Dispenser”: A component supplying precooled hydrogen to the CHSS.

“Nozzle”: A device that is connected to a hydrogen dispensing system of the hydrogen fueling station and may be coupled to a receptacle of the hydrogen electric vehicle and to supply the hydrogen fuel to the hydrogen electric vehicle.

Meanwhile, one or more conventional components may be included in a configuration of the present disclosure if necessary, and such components will be described herein to an extent that it does not obscure the technical idea and concept of the present disclosure. If the description of the conventional components may obscure the technical idea and concept of the present disclosure, however, detailed description of such components may be omitted for simplicity. For example, the use of a thermodynamic model for the hydrogen fueling control, an application of a model predictive control for a generalized dynamic control, and a preparation and a control of an artificial neural network for the training and inference of the artificial neural network may be implemented using conventional technologies, and at least some of the conventional components may be employed as elements required to embody the present disclosure.

However, the present disclosure is not intended to claim the conventional component, and the conventional component may be included as an elements of the apparatus or method of the present disclosure without deviating from the concept or spirit of the present disclosure.

Exemplary embodiments of the present disclosure will now be described in detail with reference to the accompanying drawings.

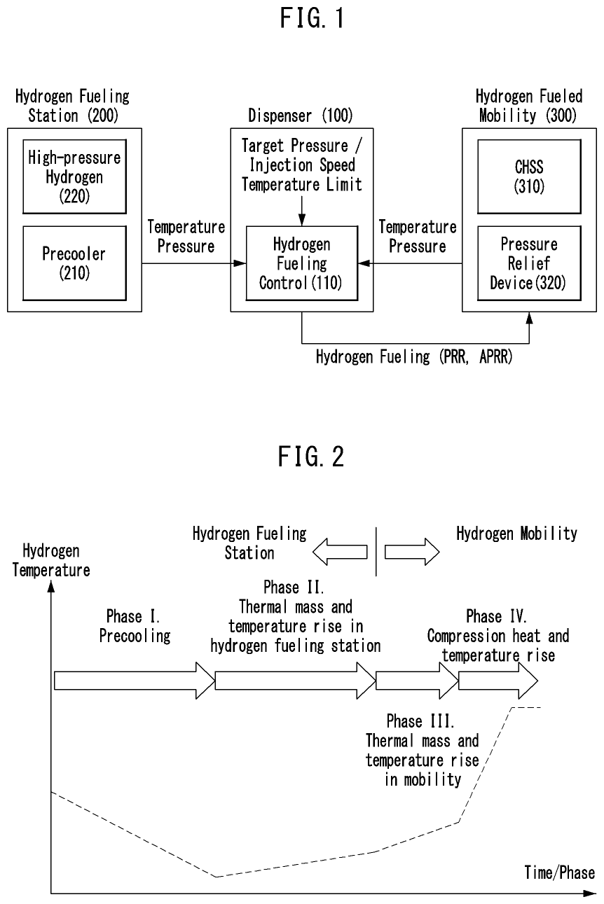

FIG. 1 is a conceptual diagram illustrating an example of a hydrogen fueling process for the hydrogen fueled mobility to which an exemplary embodiment of the present disclosure is applied.

Referring to FIG. 1, precooled hydrogen gas is supplied from a hydrogen fueling station 200 to a hydrogen fueled mobility 300 through a dispenser 100. The hydrogen fueling process may be described by parameters including the average pressure ramp rate (APRR).

In general, a hydrogen storage system installed in the vehicles may generally include a high-pressure hydrogen storage tank, a pressure control device, high-pressure piping, and an external frame. The high-pressure hydrogen storage tank has been developed and commercialized with a capacity ranging from tens to hundreds of liters, and in case of devices for vehicles, small and lightweight storage tanks connected in parallel are used to secure high capacity.

The high-pressure hydrogen storage tank is widely known as the compressed hydrogen storage system (CHSS) 310. The term “storage tank” used herein for convenience of description refers to the CHSS 310.

In a typical hydrogen storage system, hydrogen storage is controlled through an access port allowing inflow and outflow of the hydrogen gas to and from the storage tank 310. In consideration of the characteristic that hydrogen injection and discharge does not occur simultaneously, a valve, pressure reducing mechanism, and various sensors for measurement are attached to the access port and the hydrogen storage is controlled through such devices.

The dispenser 100 is in charge of an interface between the hydrogen fueling station 200 and the mobility 300. A target pressure and injection speed, etc. may be controlled based on information on the storage tank 310 of the mobility 300 and information on fuel supply of the hydrogen fueling station 200. A currently available control logic may follow the SAE J2601 (2020-05) standard.

Conventionally, the transmission of the information from the mobility 300 to the dispenser 100 is achieved through a communication method or a non-communication method. Even in the case where the communication method is employed conventionally, temperature and pressure values of the storage tank 310 in the mobility 300 are simply transmitted unidirectionally from the mobility 300 to the dispenser 100, and the dispenser 100 uses the information only as a safety reference for an emergency stop at a temperature limit or a pressure limit rather than actively utilizing the information.

All fueling control logic for the safe and rapid fueling is fulfilled in the dispenser 100, and the storage tank 310 is not equipped with any active safety management scheme but has only a safety management device that automatically releases the hydrogen through a pressure relief device (PRD) 320.

The hydrogen fueling station 200 may include a high-pressure hydrogen storage unit 220 and a precooler 210 in order to respond to an increase in the temperature of the hydrogen gas during a hydrogen fueling which will be described below with reference to FIG. 2. The precooler 210 lowers the temperature of the hydrogen gas through a precooling, so that precooled hydrogen gas is supplied to the hydrogen fueled mobility 300 via the dispenser 100.

According to an exemplary embodiment of the present disclosure, mechanical configurations of the devices for the hydrogen fueling may be generally similar to those of conventional devices, but the fueling control logic 110 in the dispenser 100 may actively control the hydrogen fueling process based on state information such as temperature and pressure data received from the mobility 300 and the hydrogen fueling station 200 and fueling status information such as a fueling rate or state of charge (SOC) of the CHSS 310.

According to an exemplary embodiment of the present disclosure, the fueling speed may be controlled in real-time based on real-time temperature data from the storage tank 310, so that the hydrogen fueling process may be operated at a highest fueling speed under a condition satisfying a safety limit, and a fueling time may be shortened as much as possible.

According to a conventional fueling protocol, boundary conditions for safety are set excessively strictly such that the precooling is excessive to the extent that the temperature of the storage tank 310 is measured to be around 40-50° C. at the time of completion of the fueling.

According to an exemplary embodiment of the present disclosure, precooling requirements and serving amounts are actively adjusted so as to optimize a cooling load of the hydrogen fueling station 200 and enhance an operation efficiency of the hydrogen fueling station 200.

The conventional protocol, which is set for a light duty hydrogen electric vehicle, has a problem that all variables must be reset and reflected in the standard in order to be applied to the fueling of a new mobility.

The fueling control logic according to an exemplary embodiment of the present disclosure is based on an artificial neural network and may be updated through a learning or training process when it is to be applied to a new device, and such a control scheme may be widely applicable to various kinds of mobilities.

The only way to prevent the overheating of the storage tank 310 of the hydrogen fueled mobility 300 in the conventional system may be to release the gas through the PRD 320 when the tank or the gas overheats above a certain temperature.

According to an exemplary embodiment of the present disclosure, a cooling system 330 which will be described below may be provided in the storage tank 310 itself to enable to increase the fueling speed and actively respond to the overheating of the storage tank 310. Thus, the safety of the hydrogen fueled mobility 300 may be improved.

An exemplary embodiment of the present disclosure allows to enhance the efficiency of the hydrogen fueling/supply process and improve the speed and the real-time operability of the hydrogen fueling/supply process while ensuring the safely in the fueling/supplying of the hydrogen fuel.

An exemplary embodiment of the present disclosure may provide a hydrogen fueling control scheme based on a model predictive control (MPC), which ensures the real-time operability.

An exemplary embodiment of the present disclosure may provide a control scheme based on an artificial neural network (ANN) model with an improved accuracy of predicting a hydrogen fueling result. The accuracy of predicting the hydrogen fueling result may be improved by applying real-time measurement data to the artificial neural network model that uses the actual fueling data along with theoretical simulation results.

An exemplary embodiment of the present disclosure may improve the efficiency of the hydrogen fueling control by integrally managing the actual measurement data and state information predicted by the model by use of an intelligent meta system (IMS).

As mentioned above, the conventional hydrogen fueling process between the hydrogen fueled mobility 300 and the hydrogen fueling station 200 is controlled by the dispenser 100. The dispenser 100 is equipped with a protocol for supplying the hydrogen into the hydrogen fueled mobility 300 according to a prescribed rule.

The protocol mounted on the dispenser 100 may be based on the international standard SAE J2601 (2020-05), which may be applied similarly to the embodiments of the present disclosure to the extent that it meets the purpose of the present disclosure.

For certain minimum requirements for safety, simulations based on thermodynamic modeling for various situations may be conducted, and a table-based static control or an MC formula-based partial real-time correction may be performed using parameters derived from the simulations.

The minimum requirements for safety may include guidelines for upper limits of the temperature and the pressure of the CHSS 310 and the fueling rate (SOC).

The simulations may be performed through thermodynamic modeling using boundary conditions including a best and a worst cases.

Such configurations may also be applied similarly to the embodiments of the present disclosure to the extent that it meets the purpose of the present disclosure.

Even when the configuration of FIG. 1 is employed, the following problems may arise in the conventional system where the state variables are not actively controlled by the dispenser 100. The problems may also be revealed in the systems relying on simulations using simple thermodynamic models.

Since the injection rate is determined in advance under an assumption of the worst (i.e., excessive) boundary conditions, an unnecessarily excessive precooling may occur and the overall fueling rate may be reduced. In such a conventional case, the injection rate may be determined simply by the average pressure ramp rate (APRR), which may hinder an active responding to a situation change. The unnecessarily excessive precooling may cause excessive energy consumptions and increase operation costs.

As mentioned above, the conventional methods have limitations in the applications. That is, the dependency on the simulation-based results may result in a limitation to a capacity or shape of the storage tank 310 actually applicable to the vehicle. In case of a new system, separate resources may be required for the development and application of the system.

Since thermodynamic model takes a lot of time to derive calculation results of mathematical equations, it is common that variables derived through the model are utilized indirectly. Accordingly, the application of the model is limited in cases where there are no variables calculated in advance. Further, thermodynamic models may reveal a lack of flexibility, e.g., a detailed adjustment of a model itself is difficult.

The conventional table-based method does not utilize the temperature of the precooled hydrogen provided by the hydrogen fueling station 200 or the temperature of the storage tank 310 measured in the mobility 300, and thus may result in a very low efficiency and a difficulty in flexibly dealing with any changes in surrounding conditions.

Though the conventional MC formula-based method corrects the precooling temperature in real-time, the calculation and application of the method are complex and there may exist limitations in the applications, which makes the expansion of the application difficult.

Therefore, there may be few alternative of which protocol was developed with a main goal of completing the safe fueling and which may actively control unexpected situations such as the excessive precooling or the overheating of the storage tank 310. These problems may bring about the increased operation costs due to the excessive cooling and delays in the fueling due to the overheating.

To solve the problems above, the present disclosure is characterized by reducing a dependency on the simulations and actively controlling the state variables by reflecting real-time measurement data.

FIG. 2 is a conceptual diagram illustrating an example of a state change that occurs in the hydrogen fueling process for the hydrogen fueled mobility to which an exemplary embodiment of the present disclosure is applied.

Referring to FIG. 2, when the hydrogen is injected into the storage tank 310, an internal temperature of the gaseous hydrogen inside the storage tank 310 increases due to compression heat.

The temperature control of the hydrogen fueling process may be performed such that the internal temperature of the storage tank 310 may maintain below 85° C. at the time of completion of the fueling of the precooled hydrogen.

In the storage tank 310, domes and bodies may be enclosed by carbon fibers of which heat transfer efficiency is low so as to block heat exchanges between the gaseous hydrogen stored in the storage tank 310 and external atmosphere during the driving of the mobility.

While the temperature of the gaseous hydrogen inside the storage tank 310 rises during the fueling process, the temperature increase on a surface of the storage tank 310 is small compared with the internal temperature increase until the fueling is completed owing to the low heat transfer property of the storage tank 310.

Such a property may block heat exchange with the outside air which can alleviate the rapid temperature rise inside the storage tank 310 during the fueling, a separate temperature management scheme may be required.

However, the conventional system does not include any cooling mechanism other than receiving precooled hydrogen gas from the hydrogen fueling station 200.

Though the hydrogen fueling time may be managed such that the temperature of the hydrogen storage tank 310 is maintained below the upper limit, e.g., 85° C., by the precooling and the control of the hydrogen injection rate at the hydrogen fueling station 200, are no additional separate measures to manage the temperature of the hydrogen storage tank 310 of the hydrogen fueled mobility 300.

As a result, it is difficult to control the temperature of the hydrogen storage tank 310 during the fueling in the hydrogen fueling station 200, especially in summer when the outside temperature is high, which may bring about problems such as a delay in the fueling.

According to an exemplary embodiment of the present disclosure, the fueling process is controlled based on a base model represented by a characteristic curve of FIG. 2 and optimal control conditions suitable for actual environments may be derived. In particular, the control of the operating load of the hydrogen fueling station 200 in the precooling stage in phase I and the fueling rates, i.e. the pressure ramp rates (PRRs) during the fueling process of Phase II through Phase IV may be optimized in consideration of real-time data according to variables such as an outside temperature, an atmospheric pressure, and weather conditions that may be measured in the actual surrounding environment unlike the conventional methods.

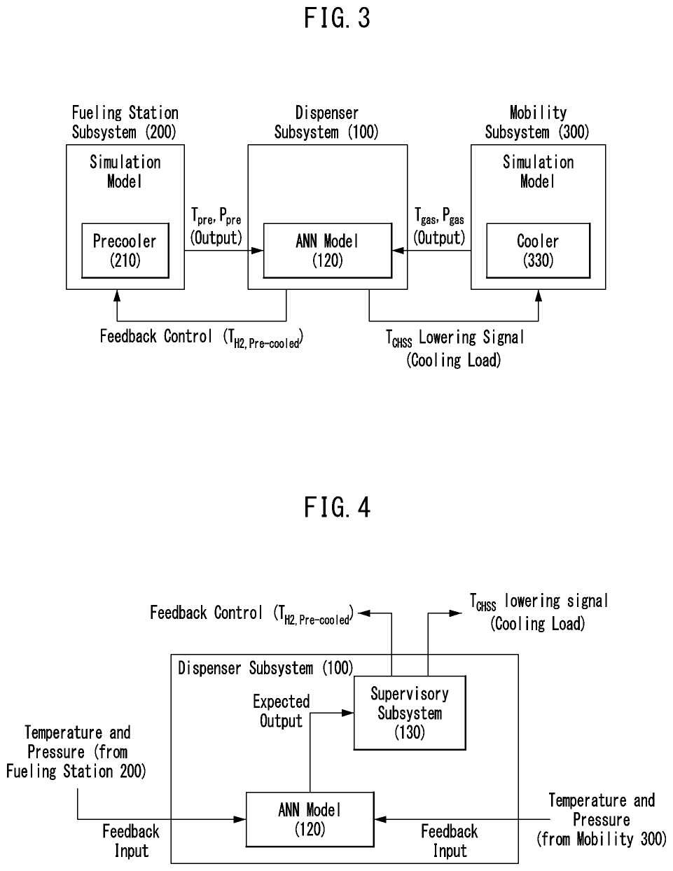

FIG. 3 is a conceptual diagram illustrating a hydrogen fueling test platform according to an exemplary embodiment of the present disclosure. Referring to FIG. 3, the hydrogen fueling test platform according to an exemplary embodiment may include a mobility subsystem 300, a fueling station subsystem 200, and a dispenser subsystem 100, all of which may be simulation models. Although an embodiment based on simulation models is illustrated in FIG. 3, the present disclosure is not limited thereto, and the mobility subsystem 300, the fueling station subsystem 200, or the dispenser subsystem 100 may be implemented by merging, combining, or alternatively selecting a simulation model and/or a data-based model based on real-time on-site dynamic data.

FIG. 4 is a detailed block diagram of the dispenser subsystem 100 shown in FIG. 3.

Referring to FIGS. 3 and 4 together, when a target precooling temperature is provided to the fueling station subsystem 200 as a control request and/or a feedback control by the dispenser subsystem 100, a precooling temperature data Tpre and a precooling pressure Ppre acquired by a simulation reflecting the precooler 210 or by measurements of actual on-site data may be output by the fueling station subsystem 200 to the dispenser subsystem 100 and transferred to an artificial neural network model 120.

In addition, when a CHSS temperature lowering signal for lowering the temperature of the CHSS (310) is provided to the mobility subsystem 300 as a control request by the dispenser subsystem 100, a gaseous temperature data Tgas and a gaseous pressure Pgas acquired by a simulation reflecting the cooler 330 or by measurements of actual on-site data may be output by the mobility subsystem 300 and transferred to the artificial neural network model 120. At this time, the temperature lowering signal may be considered as a type of cooling load (CL) in the mobility subsystem 300.

Referring to FIG. 4, in the dispenser subsystem 100, a prediction result inferred and output by the artificial neural network model 120 may be transferred to the supervisory subsystem 130. The supervisory subsystem 130 may provide the fueling station subsystem 200 with the target precooling temperature as the control request and/or the feedback control or may provide the mobility subsystem 300 with the CHSS temperature lowering signal as the control request.

The supervisory subsystem 130 shown in FIG. 4 may function as a kind of controller that controls the hydrogen fueling test process. Although it is shown in FIG. 4 as if the supervisory subsystem 130 is an independent hardware or software module mounted on the dispenser system 100 for convenience of description, the supervisory subsystem 130 may be implemented in a cloud and/or in a form of a remote server in an alternative embodiment of the present disclosure.

In addition, although the embodiment shown in FIG. 4 is based on the artificial neural network model 120, the present disclosure is not limited by the artificial neural network model 120 or the model predictive control technique. In another exemplary embodiment of the present disclosure, the real-time on-site data is fed back to the dispenser subsystem 100 in response to the hydrogen fueling control related information based on a hydrogen fueling protocol and/or the feedback control, so that the hydrogen fueling control related information and/or the feedback control may be updated or next hydrogen fueling control related information and/or feedback control may be generated based on the real-time on-site data. Another exemplary embodiment of the present disclosure may provide a hydrogen fueling protocol that does not rely upon the artificial neural network model 120 or the model predictive control, and a test method and a test platform for testing the hydrogen fueling system.

The fueling station 200 may be equipped with a plurality of hydrogen storage cylinders, each of which operates as a bank of a storage bank system. The real-time on-site data fed back by the fueling station 200 to the dispenser 100 may include the temperature and the pressure data for each bank.

The plurality of banks may be selectively connected to the dispenser 100 according to a request from the dispenser 100 and/or a selection of the fueling station 200. At this time, the temperature and the pressure information for each bank included in the real-time on-site information received by the dispenser 100 from the fueling station 200 may affect the selection and/or switching of the banks.

At least one bank in the storage bank system may change its state based on the temperature and pressure information for each bank included in the real-time on-site information received by the dispenser 100 from the fueling station 200.

For example, the temperature and the pressure of one or more of the banks in the fueling station 200 may be adjusted, as a preparatory step, to respective levels enabling the fueling based on current state information of the bank. The adjustment may be performed in response to a request of the dispenser 100 or under a control of a control logic of the fueling station 200.

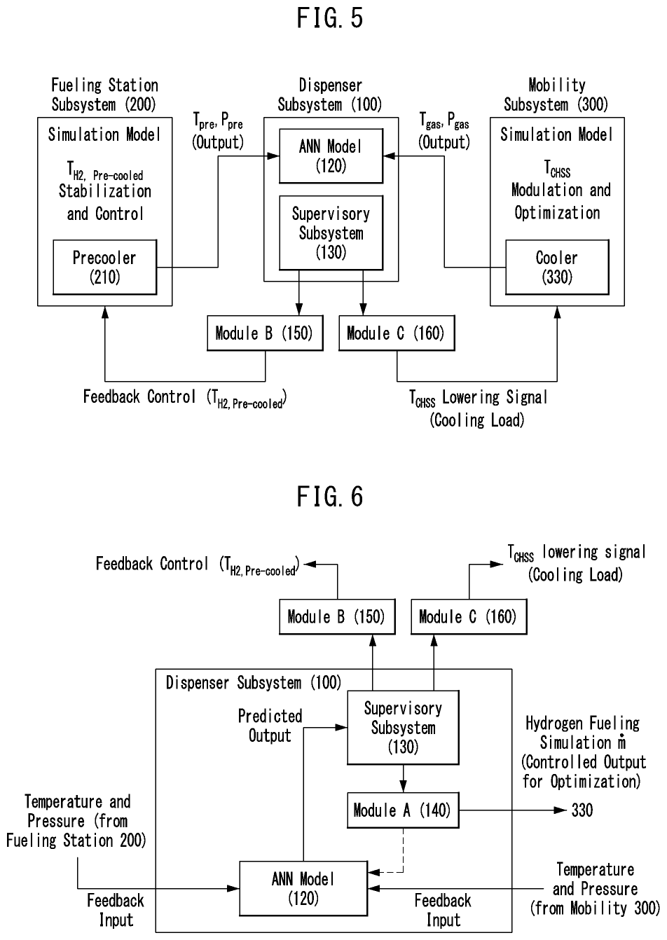

FIG. 5 is a conceptual diagram illustrating a hydrogen fueling test platform according to an exemplary embodiment of the present disclosure.

Referring to FIG. 5, a communication interface module-C 160 may be arranged between the dispenser subsystem 100 and the mobility subsystem 300 as a communication interface facilitating bidirectional communications between the dispenser subsystem 100 and the mobility subsystem 300. In addition, a communication interface module-B 150 may be arranged between the dispenser subsystem 100 and the fueling station subsystem 200 as a communication interface facilitating bidirectional communications between the dispenser subsystem 100 and the fueling station subsystem 200.

When the fueling station subsystem 200 operates as a simulation model, the mobility subsystem 300 may operate as a modulation and optimization means for the temperature of the CHSS (310).

When the mobility subsystem 300 operates as a simulation model, the fueling station subsystem 200 may operate as a stabilization and control means for the precooling temperature.

FIG. 6 is a conceptual diagram illustrating the hydrogen fueling test platform according to another exemplary embodiment of the present disclosure.

Referring to FIGS. 5 and 6 together, the supervisory subsystem 130 shown in FIG. 6 may function as a kind of controller that controls the hydrogen fueling test process.

The prediction result inferred and output by the artificial neural network model 120 may be transferred to the supervisory subsystem 130. The supervisory subsystem 130 may transmit a control request for the state of the hydrogen in the mobility tank of the hydrogen fueled mobility 300 to the hydrogen fueled mobility 300 via the communication interface module-C 160. The control request for the state of the hydrogen in the mobility tank of the hydrogen fueled mobility 300 may be a temperature lowering request for the hydrogen in the mobility tank. The temperature lowering request may be provided as the temperature lowering signal.

The supervisory subsystem 130 may transmit a control request for the state of the hydrogen supplied from the fueling station 200 to the dispenser 100 to the fueling station 200 via the communication interface module-B 150. The control request for the state of the hydrogen supplied from the fueling station 200 to the dispenser 100 may be a precooling request. The precooling request may include the target precooling temperature.

The supervisory subsystem 130 may transmit, to the hydrogen fueled mobility 300 via a communication interface module-A 140, hydrogen fueling control related information including information related to a control command/request for the hydrogen fueling process in which the hydrogen is supplied from the fueling station 200 to the mobility tank of the hydrogen fueled mobility 300 through the dispenser 100, and state information on the dispenser 100 side reflecting a result of execution of the control command/request for the hydrogen fueling process by the dispenser 100 side. The hydrogen fueling control related information may include one or more of information related to a control command for a pressure ramp rate (PRR) for fueling hydrogen into the mobility tank, and/or state information on the dispenser 100 side including the result of the execution of the control command. In addition, the hydrogen fueling control related information may include one or more of information on a variable that may affect changes in the state of the hydrogen in the mobility tank of the hydrogen fueled mobility 300, such as a real-time PRR or a mass flow rate of compressed hydrogen (m_dot) measured in kilograms per second (kg/s) and derived from a feedback control process, and/or information on the result of the execution of the control using the variable. These hydrogen fueling control related information may also affect weights or parameters of hidden layers of the artificial neural network model 120.

A thermodynamic model such as Hydrogen Filling Simulation (H2FillS), for example, may be used for a theoretical simulation. Thermodynamic model may include a model and/or software designed to track and report transient changes in one or more of the temperature, the pressure, and the mass flow of the hydrogen and/or transient changes in the state of the hydrogen in the mobility tank while the hydrogen is fueled into the hydrogen fueled mobility. However, the inventive concept of the present disclosure is not limited to a specific embodiment of thermodynamic model.

The hydrogen filling protocol may include, for example, the fueling protocol defined in the SAE J2601 standard. However, the inventive concept of the present disclosure is not limited to a specific embodiment.

Thermodynamic model can generate output data based on the modeling and the simulation when input data corresponding to the input data of the artificial neural network is applied, for example. At this time, variables of thermodynamic model may be adjusted according to the hydrogen fueling protocol. Further, different hydrogen fueling protocols may derive different output data for the same input data.

In an exemplary embodiment of the present disclosure, on-site data collected by the test platform may be provided as input data and output data of the artificial neural network, for training of the artificial neural network, instead of input data and output data of thermodynamic model. That is, some of the on-site data collected by the test platform may be provided as the input data of the artificial neural network while other some of the on-site data may be provided as ground truth data corresponding to the output data of the artificial neural network.

Internal parameters of the artificial neural network may be trained without an initialization. Alternatively, the internal parameters may be trained based on the on-site data after being initialized to certain values. For example, the input data and the output data (i.e., ground truth data) of the artificial neural network may be initialized based on thermodynamic model, and the internal parameters of the artificial neural network may be initially trained using initialized input and output data.

The training of the artificial neural network does not necessarily have to be performed by deep learning, but shallow learning may be used instead.

The test platform according to an exemplary embodiment of the present disclosure may rely on dynamic on-site data to optimize the hydrogen fueling process.

According to an exemplary embodiment of the present disclosure, a next state may be predicted by the model predictive control (MPC) technique based on the artificial neural network. In such a case, the artificial neural network model may be trained using a theoretical result, on-site data, or both of them.

In the case where the precooling function of the fueling station 200 or the cooler 310 of the mobility 300 is not available, the module-A 140 may perform the control process alone or proactively.

To analyze a state change in the process between the dispenser 100 and the fueling station 200, a training model based on the on-site data between the dispenser 100 and the hydrogen fueled mobility 300 may function as a reference for the process between the dispenser 100 and the hydrogen fueled mobility 300.

Contrarily, to analyze a state change in the process between the dispenser 100 and the hydrogen fueled mobility 300, a training model based on the on-site data between the dispenser 100 and the fueling station 200 may function as a reference for the process between the dispenser 100 and the fueling station 200.

Standardized items or variables that may optimize and accurately describe the hydrogen fueling process may be derived by collecting big data associated with a type and an individual ID of the dispenser 100, a type and an individual ID of the fueling station 200, a type and an individual ID of the mobility 300, target control states for temperatures, pressures, and/or SOC, initial states of temperatures and pressures, and a type of the hydrogen fueling protocol and training the test platform by using the dynamic on-site data corresponding to various cases.

The hydrogen fueling test system according to an exemplary embodiment of the present disclosure, which is a system for testing hydrogen fueling for a hydrogen fueled mobility, may include: the communication interface module-A 140 transmitting the hydrogen fueling control related information affecting the state of the hydrogen in the mobility tank of the hydrogen fueled mobility 300 to the hydrogen fueled mobility 300 and receiving the on-site data for the change in the state of the hydrogen in the mobility tank as a feedback corresponding to the hydrogen fueling control related information; and the supervisory subsystem 130 or controller updating the model for the hydrogen fueling process for the hydrogen fueled mobility 300 corresponding to the hydrogen fueling control related information based on the on-site data for the change in the state of the hydrogen in the mobility tank corresponding to the hydrogen fueling control related information.

The supervisory subsystem 130 may include a function of a controller. The term ‘controller’ used herein may refer to a configuration corresponding to function of the controller of the supervisory subsystem 130. An operation of the controller may mean an operation performed by the function of the controller of the supervisory subsystem 130.

The supervisory subsystem 130 or controller may obtain a difference between a simulation result for the change in the state of the hydrogen in the mobility tank corresponding to the hydrogen fueling control related information and the on-site data for the change in the state of the hydrogen in the mobility tank.

The supervisory subsystem 130 or controller may update the model 120 for the hydrogen fueling process for the hydrogen fueled mobility corresponding to the hydrogen fueling control related information based on the difference between the simulation result and the on-site data.

The supervisory subsystem 130 or controller may obtain the simulation result for the change in the state of the hydrogen in the mobility tank corresponding to the control request by using thermodynamic model tracking the transient change in one or more of the temperature, the pressure, and/or the mass flow of the hydrogen.

The supervisory subsystem 130 or controller may apply a predicted hydrogen control request including a future probable hydrogen fueling control request (for one or more time intervals at least partly including future) to the model for the hydrogen fueling process to obtain the simulation result for the change in the state of the hydrogen in the mobility tank corresponding to the hydrogen fueling control request, wherein the predicted hydrogen control request may been obtained by the model predictive control (MPC) technique.

The model 120 for the hydrogen fueling process corresponding to the hydrogen fueling control related information may be a model trained to predict the change in the state of the hydrogen in the mobility tank based on the hydrogen fueling control related information related to an execution result of a hydrogen fueling control request, and the state of the hydrogen in the mobility tank.

In particular, the model 120 for the hydrogen fueling process corresponding to the hydrogen fueling control related information may be trained to predict a future change in the state of the hydrogen in the mobility tank based on one or more of the hydrogen fueling control related information, a current state of the hydrogen in the mobility tank, a state of the hydrogen supplied to the mobility from the dispenser, and/or an ambient temperature.

The model 120 for the hydrogen fueling process corresponding to the hydrogen fueling control related information may be trained to predict the change in the state of the hydrogen in the mobility tank according to one or more of each target state of the hydrogen in the mobility tank targeted by the hydrogen fueling control related information and/or each hydrogen fueling protocol.

The model 120 may be an artificial neural network model. The supervisory subsystem 130 or controller may be trained to predict the change in the state of the hydrogen in the mobility tank based on the hydrogen fueling control related information and the state of the hydrogen in the mobility tank and using the on-site data for the change in the state of the hydrogen in the mobility tank as the ground truth data so as to update the parameters of the model 120.

The model 120 may be trained to predict the change in the state of the hydrogen in the mobility tank using the model prediction control technique.

After updating the model 120, the supervisory subsystem 130 or controller may replace at least a part of the hydrogen fueled mobility 300 side with the model 120 to acquire at least one of the simulation data and/or the on-site data for the change in the state of the hydrogen supplied to the dispenser 100 from the fueling station 200 correspondingly to a second control request sent between the dispenser 100 supplying the hydrogen to the hydrogen fueled mobility 300 and the fueling station 200 supplying the hydrogen to the dispenser 100.

After updating the model 120, the supervisory subsystem 130 or controller may replace a side of the fueling station 200 with the model 120 to acquire at least one of simulation data and on-site data for the change in the state of the hydrogen in the mobility tank of the hydrogen fueled mobility 300 correspondingly to a third control request sent between the hydrogen fueled mobility 300 receiving the hydrogen from the dispenser 100 and the dispenser 100.

The supervisory subsystem 130 or controller may determine, through the communication interface module-A 140, whether the hydrogen fueled mobility 300 is capable of actively responding to the hydrogen fueling control related information or the control request for the change in the state of the hydrogen to control the change in the state of the hydrogen in the mobility tank or not. At this time, information on communication protocols and control protocol supported by the hydrogen fueled mobility 300 and communication protocols and control protocols supported by the dispenser 100 may be shared through communications between the hydrogen fueled mobility 300 and the dispenser 100 and/or the fueling station (100), and protocols commonly supported by the hydrogen fueled mobility 300 and the dispenser 100 may be chosen as the communication protocol and the control protocol.

The hydrogen fueling control request based on the hydrogen fueling protocol may include a control command for the pressure ramp rate (PRR) for fueling the hydrogen in the mobility tank.

The hydrogen fueling control related information may include one or more of information on the hydrogen fueling control request, state information according to the execution result of the hydrogen fueling control request, or both of them. The control request for the change in the state of the hydrogen may include a control request for one or more of the temperature and/or the pressure of the hydrogen in the mobility tank.

The change in the state of the hydrogen in the mobility tank may include the change in at least one of the temperature, the pressure, and/or the state of charge (SOC).

The conventional hydrogen fueling process or hydrogen fueling control technique may be disadvantageous in that it is difficult to control the final SOC, the temperature or pressure of the nozzle, and the CHSS 310 as targeted. In addition, theoretical simulation-based hydrogen fueling technique does not match the actual on-site data due to a pressure variability, an unstable flow rate, and a high environmental variability.

The discrepancy between the simulation result and the actual on-site data may be caused at least partially by the characteristics of devices and the diversity of the environment. Even if the same hydrogen fueling protocol is used, final on-site data may differ depending on an initial value or a target value. Conversely, even if the same initial value or the same target value is assumed, the final on-site data may differ depending on the hydrogen charging protocol.

In order to solve the problems of the conventional process, an exemplary embodiment of the present disclosure may adopt a utilization of real-time on-site data, bidirectional communications between each of the devices, the predictive control technique, an integrated control of a whole system including the fueling station and the hydrogen fueled mobility, or a utilization and standardization of hydrogen fueling data based on user needs.

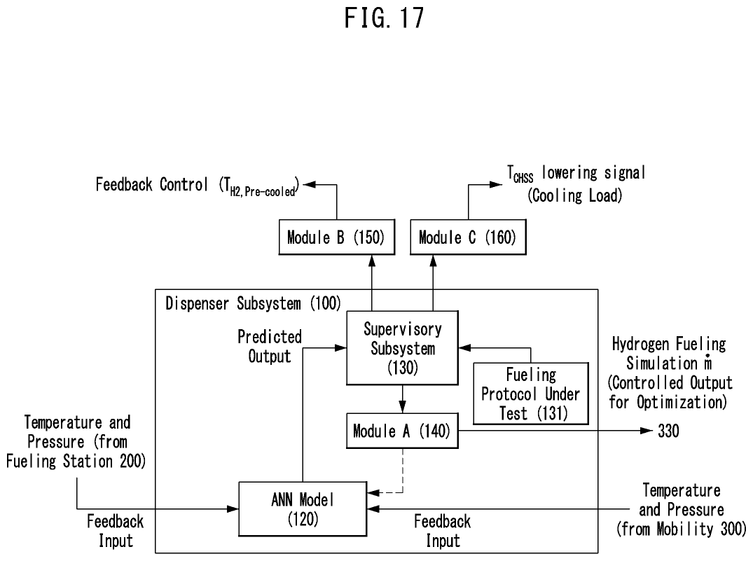

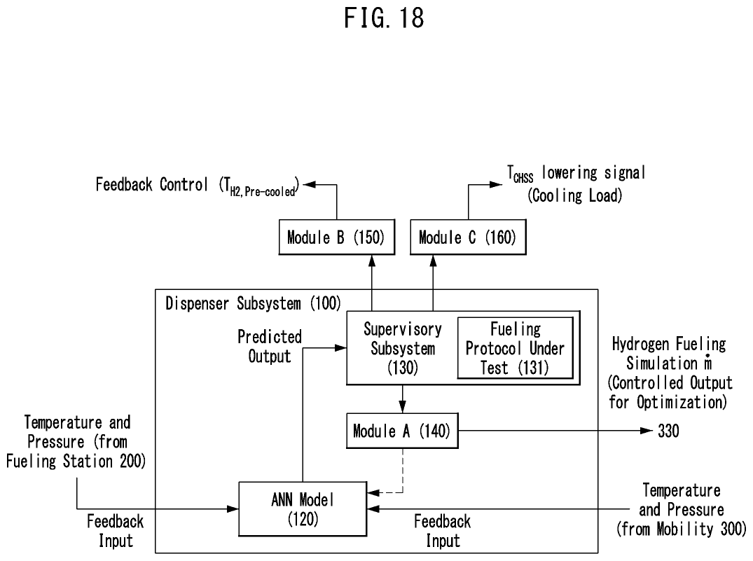

FIGS. 17 and 18 are conceptual diagrams illustrating the hydrogen fueling test platform according to other embodiments of the present disclosure.

FIG. 17 shows an embodiment in which a fueling protocol under test 131 is located outside the supervisory subsystem 130.

FIG. 18 shows an embodiment in which a fueling protocol under test 131 is located inside the supervisory subsystem 130.

Since the other configurations of the platforms of FIGS. 17 and 18 are the same as those of FIG. 6, duplicate descriptions thereof is omitted for simplicity.

In addition, an exemplary embodiment of the present disclosure may enable enhancement of an existing hydrogen fueling protocol, standardization of a format of the on-site fueling data, and compilation and diagnosis of dynamic field data.

In relation to the enhancement of the existing hydrogen fueling protocol, an exemplary embodiment of the present disclosure may include the followings.

The existing hydrogen fueling protocol may be the protocol 131 under test.

An exemplary embodiment of the present disclosure may execute an artificial neural network-based model predictive control (ANN-MPC), execute an existing hydrogen fueling protocol under the same fueling conditions, and compare a result of fueling control by the ANN-MPC and a result of the fueling control by the existing hydrogen fueling protocol to reinforce or improve the existing hydrogen fueling protocol.

The supervisory subsystem 130 may embed the protocol 131 under test to request the fueling control based on the embedded protocol and compare a control value with an ‘predicted output’ from the ANN-MPC.

The supervisory subsystem 130 or controller may execute the existing hydrogen fueling protocol to transmit the hydrogen fueling control related information to the hydrogen fueled mobility 300 via the communication interface 140 or 160 and obtain the on-site data on the change in the state of the hydrogen in the mobility tank via the communication interface 140 or 160.

The supervisory subsystem 130 or controller may obtain a hydrogen fueling control sequence from the model 120 for the hydrogen fueling process (in case that the ANN-MPC technique is used, a future time-series control sequence input may be predicted) and reinforce the existing hydrogen fueling protocol based on the hydrogen fueling control sequence provided by the model 120 for the hydrogen fueling process.

The supervisory subsystem 130 or controller may obtain result data of the execution of the hydrogen fueling control sequence provided by the model for the hydrogen fueling process and may reinforce, at least partly, the existing hydrogen fueling protocol by using the hydrogen fueling control sequence based on a comparison between the result data of the execution of the hydrogen fueling control sequence and the on-site data obtained through the existing hydrogen fueling protocol.

The fueling control result using the artificial neural network model 120 may be obtained by operating the model 120 or from a database built in advance. Basic specifications used in the fueling protocol 131 under test may not be changed, but the details, i.e., a fueling table or logics, may be reinforced or improved by with reference to the fueling control values of the artificial neural network model 120. At this time, the fueling control result using the artificial neural network model 120 may be compared with the on-site data obtained as the execution result of the fueling protocol under test 131 to partly improve the details of the fueling protocol under test 131 in case where the performance of the fueling control result using the artificial neural network model 120 is superior. The comparison between the fueling control result and the execution result of the fueling protocol under test 131 may also be performed for all or part of the hydrogen fueling process.

According to an exemplary embodiment of the present disclosure, a lumped thermodynamic model for an artificial neural network for a dispenser-vehicle Interaction may be utilized taking into account following features:
0—dimensional unsteady state mass and energy balance
1—dimensional heat transfer for mobility tank wall
CoolProp for evaluation of hydrogen properties

An exemplary embodiment of the present disclosure may perform a comparative analysis between theoretical simulation result and the actual on-site data.

An exemplary embodiment of the present disclosure may perform a predictive analysis under a specific condition in addition to conditions assumed in the hydrogen fueling protocol.

An exemplary embodiment of the present disclosure may improve the reliability of the hydrogen fueling process by collecting and processing the on-site hydrogen fueling data.

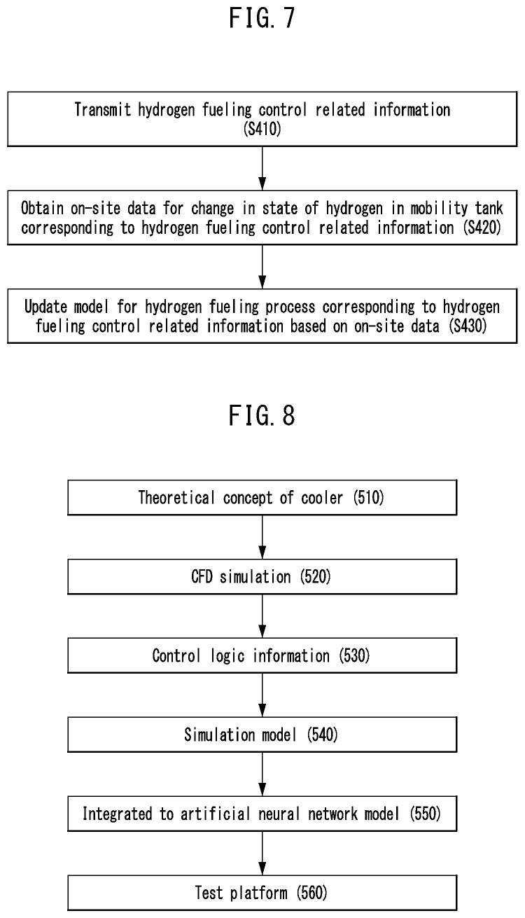

FIG. 7 is a flowchart illustrating the hydrogen fueling test method according to an exemplary embodiment of the present disclosure.

Referring to FIG. 7, the hydrogen fueling test method according to the present embodiment may include an operation S410 of transmitting the hydrogen fueling control related information affecting the state of the hydrogen in the mobility tank of the hydrogen fueled mobility to the hydrogen fueled mobility; an operation S420 of obtaining the on-site data for the change in the state of the hydrogen in the mobility tank as a feedback corresponding to the hydrogen fueling control related information; and an operation S430 of updating the model for the hydrogen fueling process for the hydrogen fueled mobility corresponding to the hydrogen fueling control related information based on the on-site data for the change in the state of the hydrogen in the mobility tank corresponding to the hydrogen fueling control related information.

Although not shown in FIG. 7, the on-site data for the change in the state of the hydrogen in the mobility tank may be first acquired by the mobility side. That is, the mobility side may acquire the on-site data for the change in the state of the hydrogen in the mobility tank regardless of the control request (for example, as an example of the hydrogen fueling control related information) that may be transmitted to the hydrogen fueled mobility. Alternatively, the control request may include an on-site data request, and the mobility side may acquire the on-site data in response to the control request including the on-site data request.

The acquisition of the on-site data may be performed by the fueling station side in addition to the hydrogen fueled mobility. In such a case, the fueling station side may acquire the on-site data regardless of the control request. Alternatively, the control request may include an on-site data request, and the fueling station side may acquire the on-site data for the state of the hydrogen stored in the fueling station and/or the hydrogen supplied to the dispenser from the fueling station in response to the control request including the on-site data request.

The on-site data refers to data obtained from the charging station side and/or the mobility side during an actual hydrogen fueling/supply process. Here, the on-site data may include data obtained in an environment where some or all of the charging station and the hydrogen fueled mobility are test environments in addition to the data obtained in the actual charging station and/or the actual mobility.

The on-site data may include data obtained from a test environment or responsive (i.e., feedback capable) apparatus corresponding to the hydrogen fueled mobility side, a test environment or responsive (i.e., feedback capable) apparatus corresponding to the hydrogen storage cylinder and dispenser side of the charging station, and/or a test environment that may be equipped with the communication module-A corresponding to a dispenser control system side or may be comprised of an executable apparatus.

The on-site data may include data obtained from a test environment or a fueling site where all the devices belong to the three test environments or apparatuses described above or the devices include one or more of the three test environments or apparatuses.

For example, the on-site data may include data obtained from a test environment or a fueling site including simulation models linked to the communication module-B 150 and the communication module-C 160 shown in FIG. 5.

The responsive (i.e., feedback capable) apparatus may refer to an apparatus including a database built based on the actual on-site data and capable of responding to a case requested through the communication module-A.

The on-site data may include and be classified into static data such as a type of the mobility tank, a volume of the mobility tank, a number of the mobility tank modules or banks and dynamic data such as the temperature and pressure of the hydrogen in the mobility tank.

The hydrogen fueling test method according to an exemplary embodiment of the present disclosure may further include an operation of obtaining the difference between the simulation result for the change in the state of the hydrogen in the mobility tank corresponding to the hydrogen fueling control related information and the on-site data for the change in the state of the hydrogen in the mobility tank.

In the operation of updating the model, the model for the change in the state of the hydrogen in the mobility tank corresponding to the hydrogen fueling control related information may be updated based on the difference between the simulation result and the on-site data.

The hydrogen fueling test method according to an exemplary embodiment of the present disclosure may further include an operation of obtaining the simulation result for the change in the state of hydrogen in the mobility tank corresponding to the hydrogen fueling control related information by using thermodynamic model tracking the transient change in one or more of the temperature, the pressure, and/or the mass flow of the hydrogen in the mobility tank.

The hydrogen fueling test method according to an exemplary embodiment of the present disclosure may further include an operation of obtaining the simulation result for the change in the state of the hydrogen in the mobility tank corresponding to the hydrogen fueling control related information by the model predictive control (MPC) technique by applying a predicted hydrogen control request including future probable hydrogen fueling control related information for one or more time intervals at least includes future, wherein the predicted hydrogen control request may be obtained by the MPC, to the model for the hydrogen fueling process.

The model for the hydrogen fueling process corresponding to the hydrogen fueling control related information may be a model trained to predict the change in the state of the hydrogen in the mobility tank based on the hydrogen fueling control related information and the state of the hydrogen in the mobility tank.

The model for the hydrogen fueling process corresponding to the hydrogen fueling control related information may be a model trained to predict the change in the state of the hydrogen in the mobility tank based on the hydrogen fueling control related information related to an execution result of a hydrogen fueling control request, and the state of the hydrogen in the mobility tank.

The model for the change in the state of the hydrogen in the mobility tank corresponding to the control request may be trained to predict the change in the state of the hydrogen in the mobility tank according to one or more of each target state of the hydrogen in the mobility tank targeted by the hydrogen fueling control related information and/or each hydrogen fueling protocol.

The model may be an artificial neural network model. In the operation of updating the model, the parameters of the model may be updated by training to predict the change in the state of the hydrogen in the mobility tank based on the hydrogen fueling control related information and the state of the hydrogen in the mobility tank and using the on-site data for the change in the state of the hydrogen in the mobility tank as the ground truth data.

The model may be trained to predict the change in the state of the hydrogen in the mobility tank using the model prediction control technique.

The hydrogen fueling test method according to an exemplary embodiment of the present disclosure may further include, after the operation of updating the model, an operation of replacing the side of the hydrogen fueled mobility with the model to acquire at least one of the simulation data and the on-site data for the change in the state of the hydrogen supplied to the dispenser from the fueling station correspondingly to the second control request sent between the dispenser supplying the hydrogen to the hydrogen fueled mobility and the fueling station supplying the hydrogen to the dispenser.

The hydrogen fueling test method according to an exemplary embodiment of the present disclosure may further include an operation of determining, through a communication, whether the hydrogen fueled mobility is capable of actively responding to the control request and controlling the change in the state of the hydrogen in the mobility tank.

FIG. 8 is a flowchart illustrating a process of configuring the test platform from a theoretical concept of the hydrogen fueling process to a formation of the test platform according to an exemplary embodiment of the present disclosure.

First, theoretical concept of the cooler 330 may be considered (510).

And, a computational fluid dynamics (CFD) simulation may be performed (520).

Then, control logic information may be obtained (530).

Subsequently, a simulation model may be implemented (540).

Afterwards, thermodynamics-based simulation model may be integrated to the artificial neural network model (550).

Finally, a test platform may be implemented by applying the real-time on-site data into the integrated model (560).

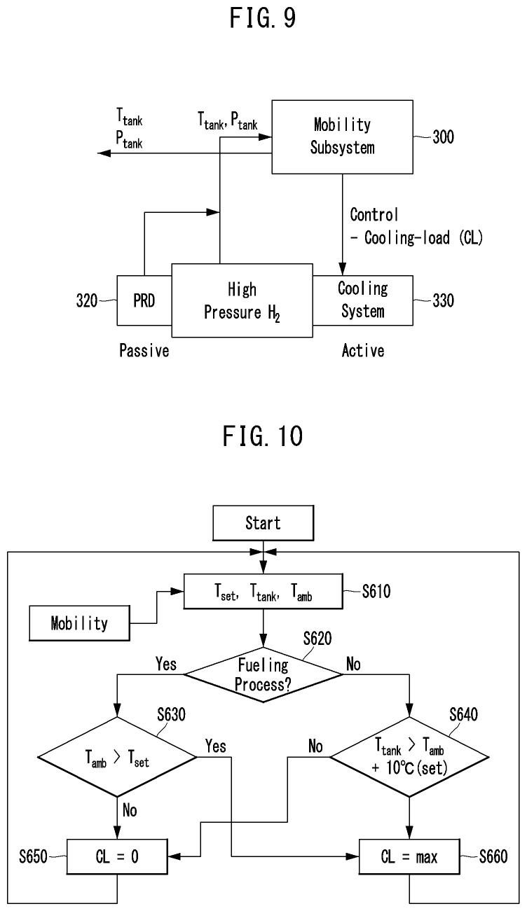

FIG. 9 is a conceptual diagram illustrating a configuration for actively and/or passively performing the control of the temperature of the hydrogen tank in the hydrogen fueled mobility during the hydrogen fueling process for the hydrogen fueled mobility according to an exemplary embodiment of the present disclosure.

Referring to FIG. 9, the control of the temperature of the hydrogen tank in the hydrogen fueled mobility 300 may be performed passively by a pressure relief device (PRD) 320 or actively by the cooler 330. In the case where the temperature control is actively performed by the cooler 300, the temperature control may be considered as controlling a cooling load and a control process for this control may be required.

FIG. 10 is a flowchart illustrating a process of determining a cooling load (CL) based on the configuration of FIG. 9.

A preset temperature, the temperature of the tank, and the ambient temperature may be acquired by the hydrogen fueled mobility 300 and nearby devices (S610).

It is checked whether the fueling process is in progress or not (S620).

If the fueling process is in progress, it is checked whether the ambient temperature is higher than the preset temperature (S630). If the ambient temperature is higher than the preset temperature, the cooling load may be controlled to its maximum (S660). If the ambient temperature is not higher than the preset temperature, the cooling load may be controlled to zero (S650).

If the fueling process is not in progress, it is checked whether the temperature of the tank is higher than the ambient temperature by a certain threshold or more (S640). In FIG. 10, the threshold may be 10 degrees Celsius. The threshold may be set by the user.

If the tank temperature is higher than the ambient temperature by the certain threshold or more, the cooling load may be controlled to the maximum (S660). If the tank temperature is not higher than the ambient temperature by the certain threshold or more, the cooling load may be controlled to zero (S650).

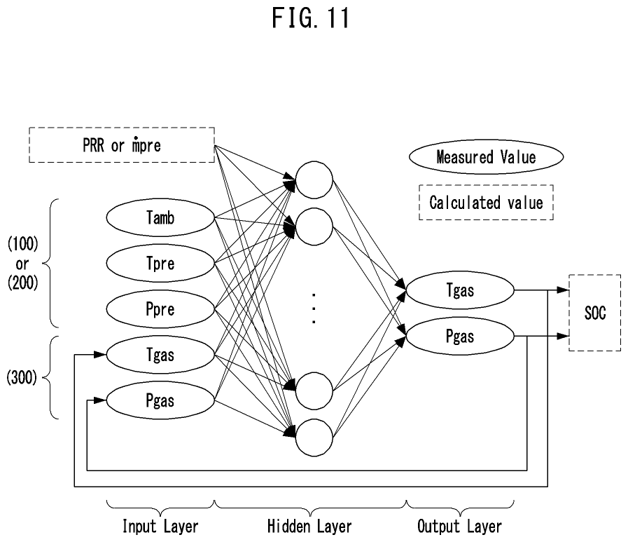

FIG. 11 is a conceptual diagram illustrating an example of the artificial neural network for controlling the hydrogen fueling process for the hydrogen fueled mobility according to an exemplary embodiment of the present disclosure.

As shown in FIG. 11, the current state measurement values are input to an input layer.

The current state measurement values, the ambient temperature T_{amb}, a precooled gas temperature Tₚᵣₑ, and a precooled gas pressure Tₚᵣₑ may be measured at a nozzle of the dispenser 100 or the hydrogen fueling station 200.

A gaseous hydrogen temperature T_{gas} and a gaseous hydrogen pressure P_{gas} may be measured at the CHSS 310 side of the hydrogen fueled mobility 300, and the actual measurement values may be input to the input layer.

During the training process of the artificial neural network, the current state measurement values may be provided to the input layer and the next state measurement values may be provided to an output layer as the ground truth data for the training of the artificial neural network. The training process of the artificial neural network may refer to a process of training a function of predicting the next state measurement value of the output layer based on a combination of the input measurement values. A correlation between the data input to the input layer and data given to the output layer is trained, which enables the predictions using theoretical results and real dynamic fueling data.

During an inference or output process using the artificial neural network, the actually measured on-site measurement values may be provided to the input layer and a prediction value for the next measurement value may be obtained as an output inferred by an operation of the artificial neural network.

The shallow learning or the deep learning may be used for the training process of the artificial neural network according to exemplary embodiments of the present disclosure, and the artificial neural network may be any type of network as long as it can meet the purpose of the present disclosure.

The values input to the input layer may be passed to the output layer through weight-based calculations in a hidden layer.

The state value output by the output layer, i.e. the prediction value for the next state, may be used to calculate a fueling state variable, e.g., a filling rate or SOC, using at least a part of thermodynamic model.

An exemplary embodiment of the present disclosure allows a hybrid control combining a theoretical simulation model and an artificial neural network. The hybrid control may fulfill certain results even through a training using a small amount of data and may achieve a desired performance that meets the purpose of the present disclosure by use of a lightweight artificial neural network.

A real-time pressure ramp rate (PRR) or a mass flow rate of compressed hydrogen (M) measured in kilograms per second (kg/s) and derived from the feedback control process may affect the weights or parameters of the hidden layer of the artificial neural network.

The artificial neural network-based hydrogen fueling technique of the present disclosure may improve an accuracy of predicting fueling results through the model. Since the actual fueling data may be used along with theoretical simulation results, the real-time measurement data may be reflected in the prediction, which may further improve the accuracy of the prediction results.

While the conventional control protocol calculates and predicts the results through a simulation customized to an individual situation, the exemplary embodiment of the present disclosure may improve the accuracy through repeated training for various situations.

Because of the difference, the accuracy according an exemplary embodiment of the present disclosure gradually improves through updates as various theoretical values and empirical results are added. Furthermore, even when a new fueling process which employs a new storage tank 310 with a different configuration or of which flow rate is changed is introduced, the model may be updated and adapted to the new fueling process through the training using additional training data. Thus, the control method may be widely applicable to various mobilities.

The model prediction control (MPC) technique may be used for the hydrogen charging control technique in the hydrogen charging test for the hydrogen fueled mobility 300 according to an exemplary embodiment of the present disclosure.

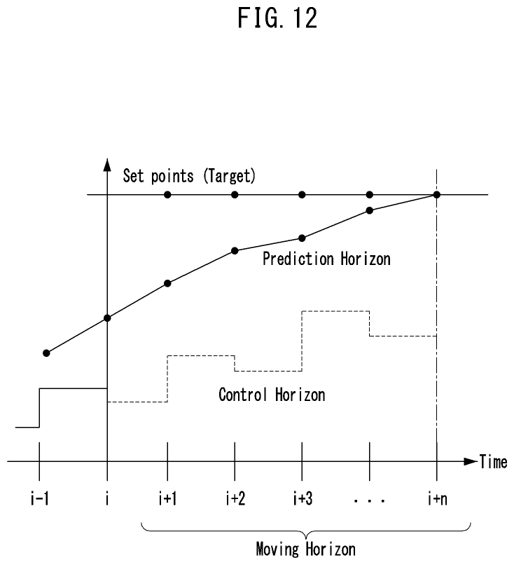

FIG. 12 is a conceptual diagram illustrating the concept of the model predictive control for the hydrogen fueling control for the hydrogen fueled mobility according to an exemplary embodiment of the present disclosure.

In an exemplary embodiment, a future fueling result may be predicted from the hydrogen fueling model and current measured data in a state that the accuracy of the hydrogen fueling model reached a certain level, and the pressure ramp rate (PRR) may be controlled in real-time based on a prediction value and a measurement value such that an optimal fueling target may be reached while certain variables such as the temperature T_{gas} or the pressure P_{gas} of the gaseous hydrogen in the gaseous hydrogen of CHSS 310 does not violate the constraints.

Referring to FIG. 12, the model predictive control scheme according to an exemplary embodiment of the present disclosure may calculate a future output value based on the prediction value of the model and the current measurement value and adjust the operation parameter or variable such that the predicted future response moves to set points or target in an optimal manner.

For example, N model-based prediction values may be derived at a current time (i). The N model-based prediction values may form a prediction horizon.

Meanwhile, N control commands or control actions required to make N model predictions may form a control horizon. Each model-based prediction value in the prediction horizon may correspond to a respective value in the control horizon.

Actually, an (i+1)-th control action which is the first control action among the N control actions derived at the current time (i) may be delivered to the system. After one time interval, new N model prediction values and new N control actions are derived at the time (i+1), and the new model prediction values and the new control actions form a new prediction horizon and a new control horizon, respectively.

The technique of controlling the system while expanding or moving the horizon in such a manner is referred to as the model predictive control. According to an exemplary embodiment of the present disclosure, the model predictive control is conducted by using the measurement values of state information or the state values including the temperature and the pressure of gaseous hydrogen in the CHSS 310 and the prediction values of the state variables.

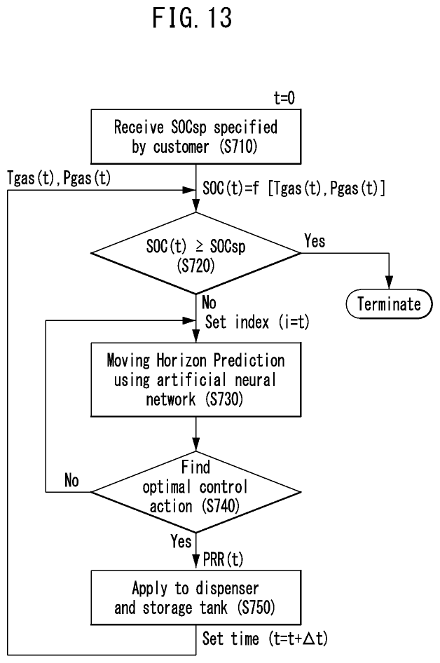

FIG. 13 is a flowchart illustrating a process of training the artificial neural network for the hydrogen fueling control according to an exemplary embodiment of the present disclosure.

A process of training the artificial neural network according to an artificial neural network-model predictive control (ANN-MPC) technique in accordance with an exemplary embodiment of the present disclosure is shown in FIG. 13.

In the exemplary embodiment shown in FIG. 13, it is assumed that N future predictions are used along with the control commands respectively corresponding thereto. The N future predictions are assumed to be acquired from the neural network model 120 having learned a function of acquiring the prediction horizon and the control horizon based on the artificial neural network and the model predictive control, in particular, so that the process that the future response reaches the set points is optimized by the model predictive control technique.

Referring to FIGS. 12 and 13, according to an exemplary embodiment, a control system may be configured based on the artificial neural network model 120, and a test platform system for real-time control may be configured based on the model predictive control to rely upon the accuracy of the artificial neural network model 120.

The test platform system for real-time control enables to control the fueling speed, the pressure ramp rate, and/or the pressure increase rate, to remain within an optimal range, by predicting the future filling results and comparing the future filling results with the actual measurement values. The constraints, a control time interval, and sensitivities may be separately set within the system logic.

Initially, the optimal control is achieved based on the real-time data from the hydrogen fueling station 200 and the mobility 300. However, when a certain event occurs during the operation of the system, the system may directly control the precooling temperature of the precooler 210 and a cooling system of the mobility 300 to enhance the overall efficiency of the hydrogen fueling process.

Referring to FIG. 13, the control process begins by receiving a SOC specified by a customer SOCₛₚ at time t=0 (S710). For example, the current SOC may be 50% and the SOC specified by a customer (SOCₛₚ) may be 85%.

A current instantaneous SOC, i.e., SOC(t), may be given as a function of the gaseous hydrogen temperature T_{gas}(t) and the gaseous hydrogen pressure P_{gas}(t), and a detailed representation of the function may be determined based on the general thermodynamic or dynamic model.

If the current SOC (SOC(t)) is greater than or equal to the specific SOC (SOCₛₚ) (S720), the hydrogen fueling procedure may be terminated. If the current SOC (SOC(t)) is smaller than the specific SOC (SOCₛₚ) (S720), an index (i) is set to i=t, and a moving horizon prediction involving the artificial neural network may be performed (S730).

The operation S730 may be performed by carrying out the model predictive control-based prediction using the artificial neural network 120 or the like. In operation S740, it may be determined whether the N predictions acquired in the operation S730 are predictions or control commands optimized or meeting an intended purpose or not.

If it is determined in the operation S740 that the N predictions are optimal predictions, a control command PRR(t) may be determined based on the N predictions and the control commands, and a control command PRR(t) may be applied to the dispenser 100 and the storage tank 310 (S750).

Afterwards, time index (t) is increased, and new measurement values for the gaseous hydrogen temperature T_{gas}(t) and the gaseous hydrogen pressure P_{gas}(t) are acquired and transferred to the input of the operation S720.

If it is determined in the operation S740 that the N predictions acquired in the operation S730 are not optimal predictions, the operation S730 may be performed again to obtain new N predictions and control commands.

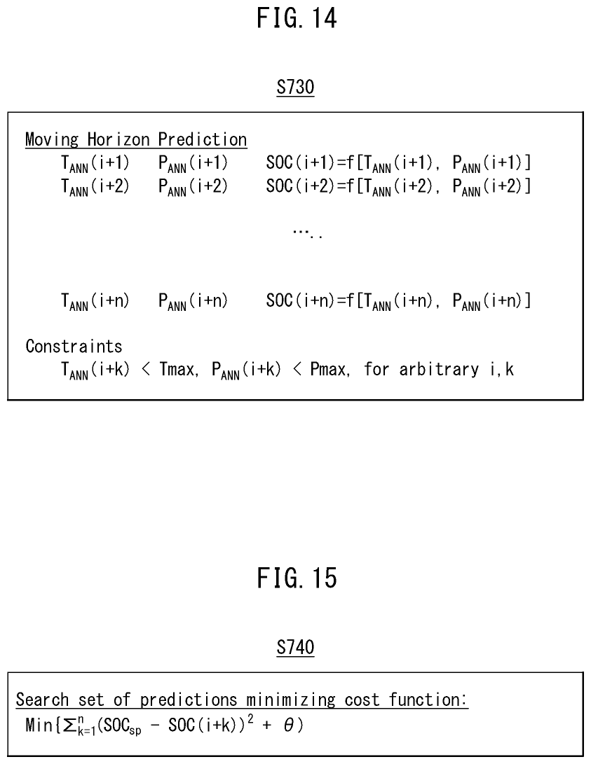

FIG. 14 is a conceptual diagram illustrating a part of the process of FIG. 13 in more detail.

Referring to FIGS. 12-14, pairs of state prediction values (T, P) satisfying the temperature limit and the pressure limit may be generated for arbitrary positive integers, i and k, in the operation S730 shown in FIG. 13.

At the current time (i=t), N state prediction values and corresponding control commands may be derived.

FIG. 15 is a conceptual diagram illustrating another part of the process of FIG. 13 in more detail.

Referring to FIG. 15, the operation S740 shown in FIG. 13 may be understood as a process of searching for a set of N predictions that minimize the cost function indicating whether the final control target, SOCsp, has been reached.

Referring to FIG. 5 and FIGS. 12-15 together, state measurement values output by the hydrogen fueled mobility 300 and including the temperature and pressure of the CHSS 310 may be provided to the artificial neural network model 120 as a feedback.

The state measurement values output by the hydrogen fueling station 200 and including the temperature and pressure of precooled gaseous hydrogen may be provided to the artificial neural network model 120 as a feedback.

The artificial neural network model 120 may provide a predicted output to the hydrogen fueling control logic 110, and the supervisory subsystem 130 may provide a future input obtained by the simulation or a model-based prediction to the artificial neural network model 120 through the communication module-A 140.

The control process based on the artificial neural network (ANN) and the model predictive control (MPC), which utilizes the simulation together with the actual measurement data, performs at least partially the simulation using the artificial neural network model 120 and uses the prediction result in the control process.

The present embodiment aims to configure an integrated control protocol for the hydrogen fueling based on real-time data, and the system may be implemented by utilizing various technical elements.

The protocol mounted on the dispenser 100 may receive the data of the precooled gaseous hydrogen from the hydrogen fueling station 200 and the data of the storage tank 310 from the mobility 300 as real-time input values, and may generate output data by the mounted model to control the filling speed, the pressure ramp rate (PRR), and/or the mass flow rate (m_dot).

When an event such as an external environmental change occurs, the integrated fueling control model in the dispenser 100 may directly control the precooling temperature of the hydrogen fueling station 200 and the cooling system of the mobility 300 to generally adjust the filling speed, the pressure ramp rate (PRR), and/or the mass flow rate (m_dot), and a process efficiency.

A precooling system or precooler 210 of the hydrogen fueling station 200 may include an independent cooling stabilization system separately to complement the control protocol.

In terms of temperature stabilization, the cooling stabilization system of the precooler 210 may be independently controlled, but a control target value thereof may be changed integrally by the protocol of the dispenser 100.

Additional functions related to the temperature stabilization may be given to the precooler 210 to improve the economic efficiency of the hydrogen fueling station 200 and complement the functions of the integrated control protocol.

The precooling temperature varies according to the initial temperature and flow rate of the gaseous hydrogen supplied to the precooler 210. To compensate for the variation, a new precooler structure to stabilize the temperature is proposed in an exemplary embodiment of the present disclosure.

The precooler 210 according to an exemplary embodiment of the present disclosure may include a control logic for a control of its own temperature and an interface with the protocol.

The storage tank 310 of the mobility 300 may include a forced cooling system, which may partially cool the compression heat generated during the hydrogen fueling and thus improve the filling speed. The fueling protocol may also be involved in the operation and control of the forced cooling system of the storage tank 310.

In an exemplary embodiment of the present disclosure, a temperature management function may be provided to the storage tank 310 of the mobility 300 to improve the hydrogen filling speed and to complement the function of the integrated control protocol.

In an exemplary embodiment of the present disclosure, the storage tank 310 of the mobility 300 may include a self-cooling system to increase the overall filling speed and enhance the safety of the mobility 300. The storage tank 310 may include a control logic for the operation thereof and an interface with the protocol.

The integrated control according to an exemplary embodiment of the present disclosure may improve the current fueling efficiency and facilitate the preparation for the next fueling procedure.

In a T40 station where the precooling temperature of the precooler 210 is set to −40° C., when the precooling temperature reached the target value but the outside temperature is higher than a preset value and the increasing rate of the temperature of the storage tank 310 side is larger than expected, a control signal or current state information may be transmitted to the mobility 300 or the storage tank 310 so that the self-cooling system of the storage tank 310 may be operated.

Contrarily, when the precooling temperature of the precooler 210 is set to −40° C. but it is determined that the precooling is excessive taking into account the external environment and the actual data, the target value for the precooling temperature may be adjusted (to −35° C., for example).

When the target precooling temperature and the temperature of the storage tank 310 are required to be controlled additionally, the control information or the control commands may be transmitted from the dispenser 100 to both the mobility 300 and the hydrogen fueling station 200.

According to an exemplary embodiment of the present disclosure, the self-cooling systems of the mobility 300 and the hydrogen fueling station 200 may be controlled independently or may be controlled in response to a signal from the dispenser 100.

The integrated control method for the hydrogen fueling according to an exemplary embodiment may further include an operation of determining whether the current state measurement value satisfies the constraints.

The constraints may include a condition that the temperature and the pressure of the compressed hydrogen storage system (CHSS) in the hydrogen electric mobility do not exceed the temperature limit and the pressure limit, respectively.

An exemplary embodiment of the present disclosure allows to enhance the efficiency of the hydrogen fueling/supply process and improve the speed and the real-time operability of the hydrogen fueling/supply process while safely fueling/supplying the hydrogen fuel.

An exemplary embodiment of the present disclosure allows to implement a test method and a test platform enabling a precisely modeling of the hydrogen fueling/supply process based on real-time on-site dynamic data.

An exemplary embodiment of the present disclosure allows to implement a test method and a test platform enabling to provide a model capable of precisely controlling the hydrogen fueling/supply process by taking into account the difference between the result of modeling and simulation by a theoretical model and the real-time on-site data or both the result of the modeling and simulation and the real-time on-site data.

An exemplary embodiment of the present disclosure enables to implement a test method for a hydrogen fueling control ensuring the real-time operability based on a model predictive control (MPC).

An exemplary embodiment of the present disclosure enables to implement a test method for the hydrogen fueling control with an enhanced accuracy in a prediction of a hydrogen fueling result based on an artificial neural network (ANN) model.

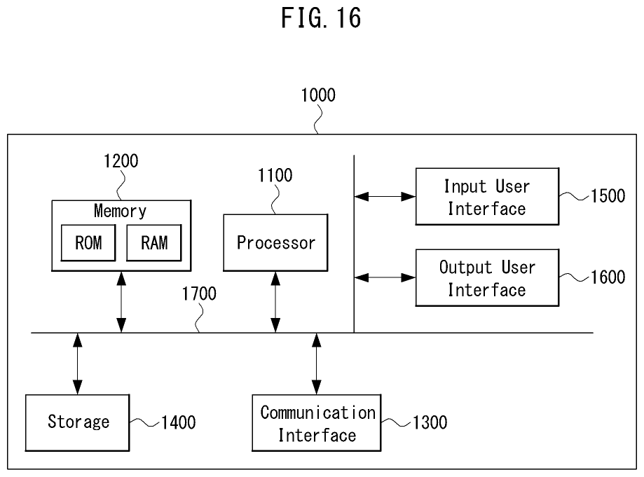

FIG. 16 is a block diagram showing a generalized configuration of a hydrogen fueling control apparatus, a hydrogen fueling control system, a hydrogen fueling test platform, a hydrogen fueling test system, or a computing system capable of performing at least a portion of the processes of FIGS. 1-15.

The controller or the supervisory system 130 controlling the hydrogen fueling test process may be disposed on the dispenser 100 side. The supervisory system 130, and/or communication interface 140, 150, or 160, solely or in cooperation, controlling the hydrogen fueling test process may be distributed in all or some of the dispenser 100, the hydrogen fueling station 200, or the hydrogen fueled mobility 300 to control at least some of the dispenser 100, the hydrogen fueling station 200, or the hydrogen fueled mobility 300.

The controller or the communication interface 140, 150, or 160 constituting the hydrogen fueling test platform and/or the system may be implemented in a form of a computing system including a memory 1200 and a processor 1100 electronically connected to the memory 1200.

At least some processes of the hydrogen fueling test method according to an exemplary embodiment of the present disclosure may be performed by the computing system 1000 of FIG. 16.

Referring to FIG. 16, the computing system 1000 according to an exemplary embodiment of the present disclosure may include a processor 1100, a memory 1200, a communication interface 1300, a storage device 1400, an input interface 1500, and an output interface 1600, and a system bus 1700.

The computing system 1000 according to an exemplary embodiment of the present disclosure may include at least one processor 1100 and the memory 1200 storing program instructions instructing the at least one processor 1100 to perform at least one process step. At least some of the operations or process steps of the method according to an exemplary embodiment of the present disclosure may be performed by the at least one processor 1100 loading and executing the program instructions from the memory 1200.

The processor 1100, which executes the program instructions or commands stored in the memory 1200, may include a central processing unit (CPU) or a graphics processing unit (GPU) or may be implemented by another kind of dedicated processor suitable for performing the method of the present disclosure.

Each of the memory 1200 and the storage device 1400 may include at least one of a volatile storage medium or a non-volatile storage medium. For example, the memory 1200 may be comprised of at least one of a read only memory (ROM) and/or a random access memory (RAM).

Additionally, the computing system 1000 may include the communication interface 1300 that performs communications through a wireless communication network.

Additionally, the computing system 1000 may further include the storage device 1400, the input interface 1500, and the output interface 1600.

The components of the computing system 1000 may be connected to each other by the system bus 1700 to communicate with each other.

The computing system 1000 according to an exemplary embodiment of the present disclosure may be any data processing device capable of communications through a network such as a desktop computer, a laptop computer, a notebook PC, a smartphone, a tablet PC, a mobile phone, a smart watch, smart glasses, an e-book reader, a portable multimedia player (PMP), a portable game console, a navigation device, a digital camera, a digital multimedia broadcasting (DMB) player, a digital audio recorder, a digital audio player, a digital video recorder, a digital video player, and a personal digital assistant (PDA).

The device and method according to exemplary embodiments of the present disclosure can be implemented by computer-readable program codes or instructions stored on a computer-readable intangible recording medium. The computer-readable recording medium includes all types of recording device storing data which can be read by a computer system. The computer-readable recording medium may be distributed over computer systems connected through a network so that the computer-readable program or codes may be stored and executed in a distributed manner.

The computer-readable recording medium may include a hardware device specially configured to store and execute program instructions, such as a ROM, RAM, and flash memory. The program instructions may include not only machine language codes generated by a compiler, but also high-level language codes executable by a computer using an interpreter or the like.

Some aspects of the present disclosure described above in the context of the device may indicate corresponding descriptions of the method according to the present disclosure, and the blocks or devices may correspond to operations of the method or features of the operations. Similarly, some aspects described in the context of the method may be expressed by features of blocks, items, or devices corresponding thereto. Some or all of the operations of the method may be performed by use of a hardware device such as a microprocessor, a programmable computer, or electronic circuits, for example. In some exemplary embodiments, one or more of the most important operations of the method may be performed by such a device.

In some exemplary embodiments, a programmable logic device such as a field-programmable gate array may be used to perform some or all of functions of the methods described herein. In some exemplary embodiments, the field-programmable gate array may be operated with a microprocessor to perform one of the methods described herein. In general, the methods are preferably performed by a certain hardware device.

The description of the disclosure is merely exemplary in nature and, thus, variations that do not depart from the substance of the disclosure are intended to be within the scope of the disclosure. Such variations are not to be regarded as a departure from the spirit and scope of the disclosure. Thus, it will be understood by those of ordinary skill in the art that various changes in form and details may be made without departing from the spirit and scope as defined by the following claims.

1. A hydrogen fueling test method for a hydrogen fueled mobility, comprising:
transmitting hydrogen fueling control related information affecting a state of hydrogen in a mobility tank of the hydrogen fueled mobility to the hydrogen fueled mobility;
obtaining on-site data for a change in the state of the hydrogen in the mobility tank as a feedback corresponding to the hydrogen fueling control related information; and
updating a model for a hydrogen fueling process for the hydrogen fueled mobility corresponding to the hydrogen fueling control related information based on the on-site data for the change in the state of the hydrogen in the mobility tank corresponding to the hydrogen fueling control related information.

2. The hydrogen fueling test method of claim 1, further comprising:
obtaining a difference between a simulation result for the change in the state of the hydrogen in the mobility tank corresponding to the hydrogen fueling control related information and the on-site data for the change in the state of the hydrogen in the mobility tank,
wherein, while updating the model, the model for the change in the state of the hydrogen in the mobility tank corresponding to the hydrogen fueling control related information is updated based on the difference between the simulation result and the on-site data.

3. The hydrogen fueling test method of claim 2, further comprising:
obtaining the simulation result for the change in the state of the hydrogen in the mobility tank corresponding to the hydrogen fueling control related information by using a thermodynamic model tracking a transient change in one or more of temperature, pressure, or mass flow of the hydrogen in the mobility tank.

4. The hydrogen fueling test method of claim 2, further comprising:
obtaining the simulation result for the change in the state of the hydrogen in the mobility tank corresponding to the hydrogen fueling control related information by applying a predicted hydrogen control request obtained by a model predictive control (MPC) technique to the model for the hydrogen fueling process.

5. The hydrogen fueling test method of claim 1, wherein the model for the hydrogen fueling process corresponding to the hydrogen fueling control related information is a model trained to predict the change in the state of the hydrogen in the mobility tank based on the hydrogen fueling control related information and the state of the hydrogen in the mobility tank.

6. The hydrogen fueling test method of claim 5, wherein the model for the hydrogen fueling process corresponding to the hydrogen fueling control related information is a model trained to predict the change in the state of the hydrogen in the mobility tank according to one or more of each target state of the hydrogen in the mobility tank targeted by the hydrogen fueling control related information or each hydrogen fueling protocol.

7. (canceled)

8. The hydrogen fueling test method of claim 5, wherein the model is a model trained to predict the change in the state of the hydrogen in the mobility tank using a model prediction control technique.

9. The hydrogen fueling test method of claim 5, further comprising:
after updating the model, replacing a part of the hydrogen fueled mobility with the model to obtain one or more of the simulation data or the on-site data for the change in a state of hydrogen supplied to a dispenser from a fueling station correspondingly to a second control request sent between the dispenser supplying hydrogen to the hydrogen fueled mobility and the fueling station supplying hydrogen to the dispenser.

10. The hydrogen fueling test method of claim 1, further comprising:
determining, through a communication, whether the hydrogen fueled mobility is capable of actively responding to the hydrogen fueling control related information and controlling the change in the state of the hydrogen in the mobility tank.

11-12. (canceled)

13. The hydrogen fueling test method of claim 1, wherein transmitting the hydrogen fueling control related information to the hydrogen fueled mobility and obtaining the on-site data for the change in the state of the hydrogen in the mobility tank are performed based on an existing fueling protocol.

14. The hydrogen fueling test method of claim 13, further comprising:
obtaining a hydrogen fueling control sequence from the model for the hydrogen fueling process; and
reinforcing the existing hydrogen fueling protocol based on the hydrogen fueling control sequence obtained from the model for the hydrogen fueling process.

15. The hydrogen fueling test method of claim 13, further comprising:
obtaining result data of an execution of the hydrogen fueling control sequence obtained from the model for the hydrogen fueling process,
wherein, in reinforcing the existing hydrogen fueling protocol, the existing hydrogen fueling protocol is partly reinforced by using the hydrogen fueling control sequence based on a comparison between the result data of the execution of the hydrogen fueling control sequence and on-site data obtained by the existing hydrogen fueling protocol.

16. A hydrogen fueling test system for a hydrogen fueled mobility, comprising:
a communication interface configured to transmit hydrogen fueling control related information affecting a state of hydrogen in a mobility tank of a hydrogen fueled mobility to the hydrogen fueled mobility and receive on-site data for a change in the state of the hydrogen in the mobility tank as a feedback corresponding to the hydrogen fueling control related information; and
a controller configured to update a model for the change in the state of the hydrogen in the mobility tank corresponding to the hydrogen fueling control related information based on the on-site data for the change in the state of the hydrogen in the mobility tank corresponding to the hydrogen fueling control related information.

17. The hydrogen fueling test system as claimed in claim 16, wherein the controller is configured to obtain a difference between a simulation result for the change in the state of the hydrogen in the mobility tank corresponding to the hydrogen fueling control related information and the on-site data for the change in the state of the hydrogen in the mobility tank,
wherein the controller is configured to update the model for the change in the state of the hydrogen in the mobility tank corresponding to the hydrogen fueling control related information based on the difference between the simulation result and the on-site data.

18. The hydrogen fueling test system as claimed in claim 16, wherein the controller is configured to obtain the simulation result for the change in the state of the hydrogen in the mobility tank corresponding to the hydrogen fueling control related information by using a thermodynamic model tracking a transient change one or more of temperature, pressure, or mass flow of the hydrogen in the mobility tank.

19. The hydrogen fueling test system as claimed in claim 16, wherein the controller is configured to obtain the simulation result for the change in the state of the hydrogen in the mobility tank corresponding to the hydrogen fueling control related information by applying a predicted hydrogen control request obtained by a model predictive control (MPC) technique to the model for the hydrogen fueling process.

20. The hydrogen fueling test system as claimed in claim 16, wherein the model for the change in the state of the hydrogen in the mobility tank corresponding to the hydrogen fueling control related information is a model trained to predict the change in the state of the hydrogen in the mobility tank based on the hydrogen fueling control related information and the state of the hydrogen in the mobility tank.

21-23. (canceled)

24. The hydrogen fueling test system as claimed in claim 16, wherein the controller is configured to execute an existing fueling protocol to transmit the hydrogen fueling control related information to the hydrogen fueled mobility through the communication interface and obtain the on-site data for the change in the state of the hydrogen in the mobility tank through the communication interface.

25. The hydrogen fueling test system as claimed in claim 24, wherein the controller is configured to obtain a hydrogen fueling control sequence from the model for the hydrogen fueling process,
wherein the controller is configured to reinforce the existing hydrogen fueling protocol based on the hydrogen fueling control sequence obtained from the model for the hydrogen fueling process.

26. The hydrogen fueling test system as claimed in claim 25, wherein the controller is configured to obtain result data of an execution of the hydrogen fueling control sequence obtained from the model for the hydrogen fueling process,
wherein the controller is configured to partly reinforce the existing hydrogen fueling protocol by using the hydrogen fueling control sequence based on a comparison between the result data of the execution of the hydrogen fueling control sequence and on-site data obtained by the existing hydrogen fueling protocol.
